(19) United States
(12) Patent Application Publication
(10) Pub. No.: US 2006/0278469 A1
(43) Pub. Date: Dec. 14, 2006

(54) Sponge bob singing in the shower toy

(75) Inventors: Alexander L. Baytman, Fairlawn, NJ (US); Albert J. Ferrigno, Garden City, NY (US)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: Fisher-Price

(21) Appl. No.: 11/358,694

(22) Filed: Feb. 21, 2006

Related U.S. Application Data
(60) Provisional application No. 60/654,844, filed on Feb. 18, 2005.

(51) Int. Cl. H05K 5/00

(52) U.S. Cl. 181/149

(57) ABSTRACT

A waterproof housing is provided with an upper shell piece having a cone positioned over a non-waterproof (e.g. paper) speaker. The cone has conical stepped depressions mimicking the shape of the speaker. A speaker retainer presses the speaker in an air tight seal to the upper shell to assure that air is trapped in the chamber formed by the speaker and the upper shell. The circumference of the cone is a waveform, which allows a stiffer center plastic portion of the cone to vibrate when the sound waves hit it. More particularly, the cone is coupled to a cylindrical collar portion of the upper shell by a web of plastic material sufficiently thin so that the cone vibrates in sync with the speaker and emits the sound.

### CROSS-REFERENCE TO RELATED APPLICATIONS

This application claims the benefit of U.S. Provisional Patent Application No. 60/654,844, filed Feb. 18, 2005 entitled “Sponge Bob Singing In The Shower Toy.”

### FIELD OF THE INVENTION

The invention relates to water toys and, in particular to sound generating water toys.

### SUMMARY OF THE INVENTION

The invention is a waterproof speaker assembly in a water toy and methods of making the same as shown and described herein.

### BRIEF DESCRIPTION OF THE SEVERAL VIEWS OF THE DRAWINGS

The following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a side perspective view a first embodiment of the toy;

FIG. 2 is a cross sectional view along the central longitudinal plane of the FIG. 1 toy;

FIG. 3 shows the toy of FIG. 1 and FIG. 2 partially broken away along the central longitudinal plane in a perspective view;

FIG. 4 depicts a stand alone, waterproof, speaker housing;

FIG. 5 depicts the housing of FIG. 4 with the perforated cover shell removed exposing the top of the sealed sound cone; and

FIG. 6 shows the housing of FIG. 5 taken apart to expose the interior of the sound cone, the paper speaker and the base to which the sound cone is attached.

### DETAILED DESCRIPTION OF THE INVENTION

This is a design for an electronic shower toy. Since water can leak into the toy through the Speaker Grille (8), an all-encompassing plastic Electronics Housing (1) was designed to protect a conventional, non-waterproof (e.g. paper) Speaker (3) and the other electronics (not depicted). Covering the Speaker (3) with a solid plastic piece would not allow any sound to pass through. Therefore, the top shell (2) of the Electronics Housing (1) is designed as a Cone (2a), with conical stepped depressions mimicking the shape of the Speaker (3). The Speaker Retainer (6) presses the Speaker (3) in a tight seal to the upper shell (2) of the Electronics Housing (1), to assure that no sound or air trapped in the chamber formed by the Speaker (3) and the upper shell (2) will leak out. The circumference of the plastic Cone (2a) is a waveform, which allows the stiff center plastic to vibrate when the sound waves hit it. The Speaker (3) vibrates and pushes the air in waves towards the plastic Cone. The Cone (2a) materials is sufficiently thin or more preferably, coupled to the Cylindrical Collar portion (2b) of the upper shell (2) supporting the Cone (2a) by a sufficiently thin web of plastic material so that the Cone vibrates in sync with the Speaker and emits the sound, which then escapes through the Speaker Grille (8).

The Upper Shell (2) and Battery Compartment (7) of the Electronics Housing (1) may be sonic welded or adhered together or otherwise held together to fully seal in the electronics. Drain Holes (10) are added at the bottom of the Housing (9) to allow any water to escape that does leak in through the Speaker Grille (8). A Gasket (5) is recessed in the Battery Door (4) to prevent any water from leaking into the Battery Compartment (7).

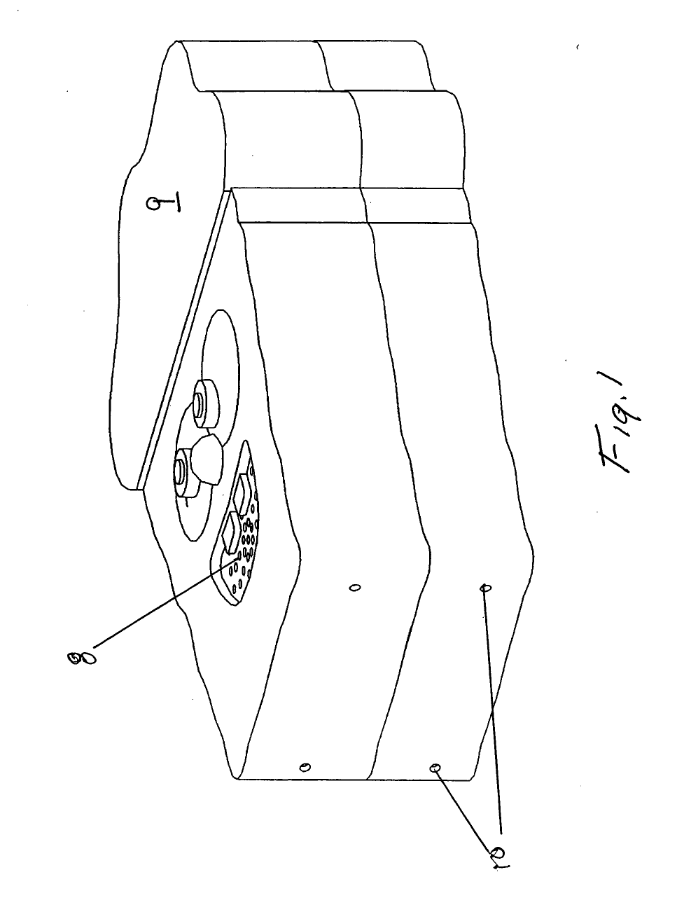

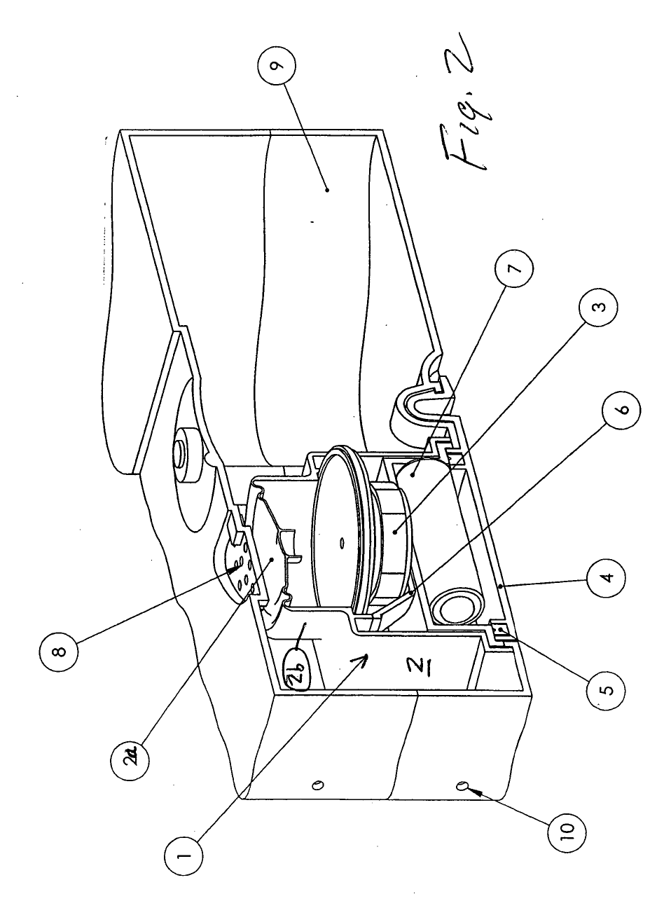

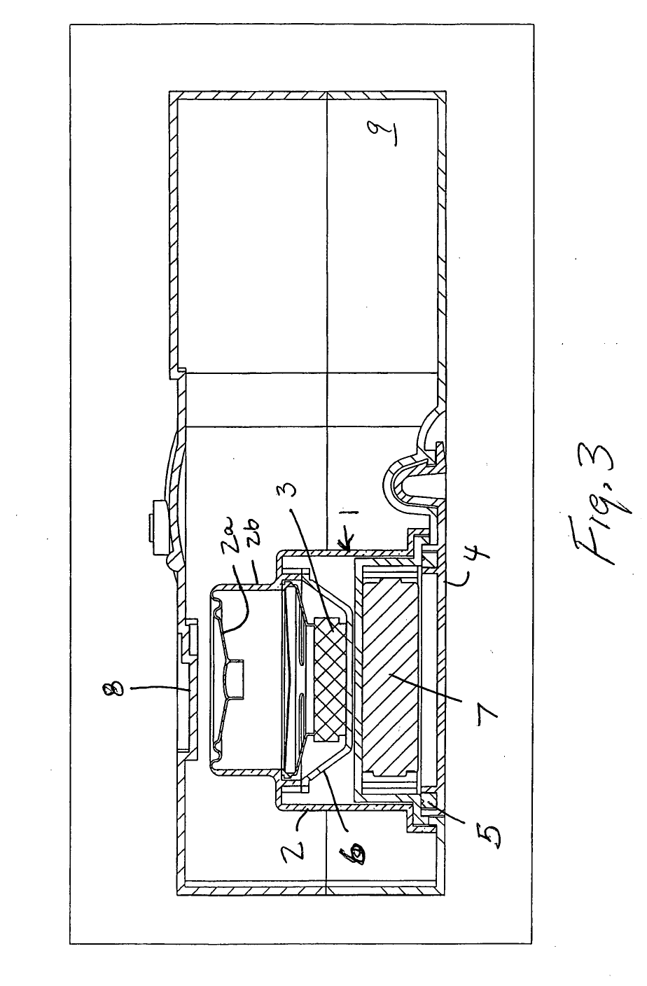

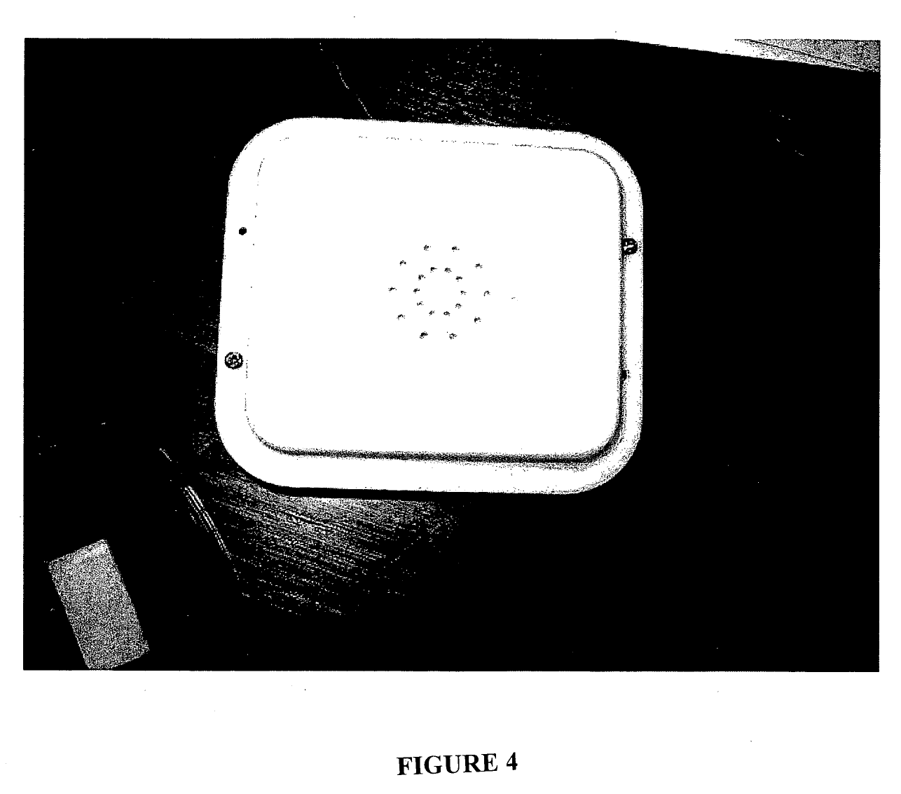

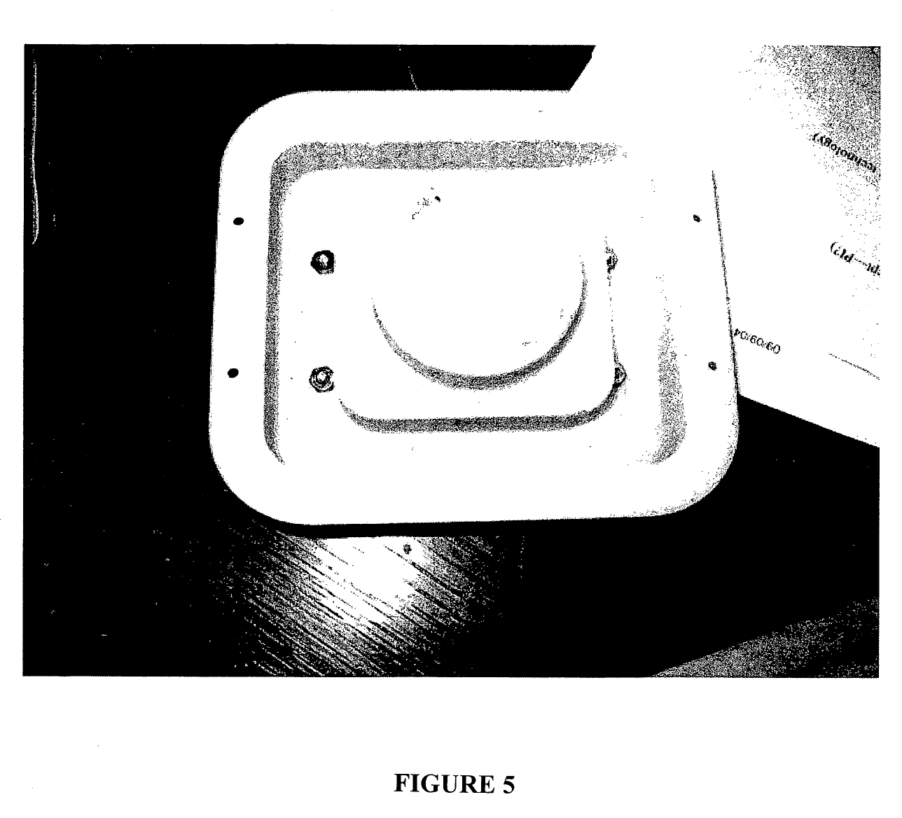

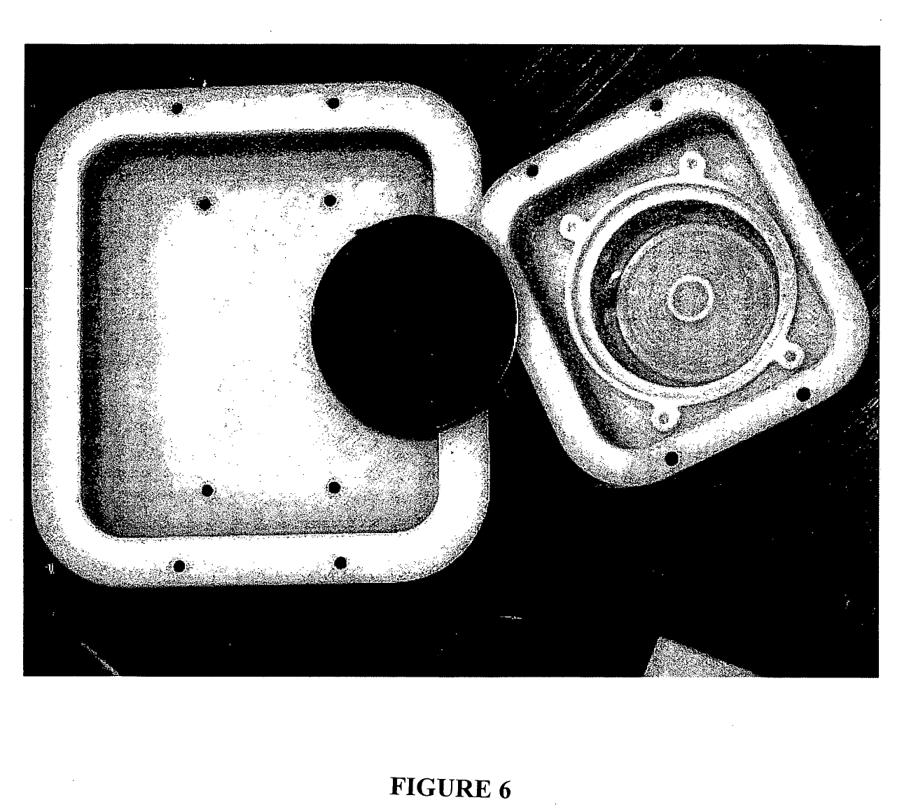

The components of FIGS. 4-6 are numbered similarly to the corresponding components of FIGS. 1-3 with the addition of an apostrophe after each relevant number. Referring to FIG. 6, the face of the paper Speaker (3′), which is exposed in that figure, is received in a seat (12) to seal the plastic chamber above it formed by Cylindrical Collar (2b′) and Cone (2a′) of the upper Housing shell (2) and pressed by base member (4′) against the seat. The battery compartment/door (7/4) of FIGS. 1-3, is replaced simply by a solid plastic base member (4′). A conventional waterproof seal is provided between the base member (4′) and the upper shell (2′) of the housing (1′). The seal may be provided by a separate gasket member like seal (5) or formed directly between upper shell (2′) and base member (4′) by sonic weld, adhesive or the like. If desired, a space can be provided between the Speaker (3), (3′) and the battery compartment door (4) or base member (4′) for an interior chamber between the Speaker (3), (3′) and the door or base (4), (4′) to receive the electronics used to control the operation of the Speaker (3), (3′).

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. A waterproof speaker assembly as shown and described.

2. A method of waterproofing a speaker assembly as shown and described.
